(19) United States
(12) Patent Application Publication
(10) Pub. No.: US 2013/0321030 A1
(43) Pub. Date: Dec. 5, 2013

(54) MOVING AVERAGE FILTER BASED ON CHARGE SAMPLING AND MOVING AVERAGE FILTERING METHOD USING THE SAME

(71) Applicant: ELECTRONICS AND TELECOMMUNICATIONS RESEARCH INSTI, Daejeon (KR)

(72) Inventors: Jang-Hyun Park, Seoul (KR); Seong-Hoon Choi, Seoul (KR); In-Su Jang, Seoul (KR); Chang-Beom Kim, Seoul (KR); Yong-Ho Cho, Daejeon (KR); Soo-Hwan Shin, Daejeon (KR); Soon-Jae Kweon, Daejeon (KR); Hyung-Joun Yoo, Daejeon (KR)

(73) Assignee: ELECTRONICS AND TELECOMMUNICATIONS RESEARCH INSTITUTE, Daejeon (KR)

(21) Appl. No.: 13/675,285

(22) Filed: Nov. 13, 2012

(30) Foreign Application Priority Data
May 30, 2012 (KR) 10-2012-0057414

(51) Int. Cl. H03K 5/00

(52) U.S. Cl. CPC H03K 5/00
USPC 327/103

(57) ABSTRACT

The present invention relates to a movement average filter based on charge sampling and a moving average filtering method using the same. The moving average filter includes a voltage-current converter and a first sampling unit. The voltage-current converter converts an input voltage signal into an input current signal and outputs the input current signal. The first sampling unit includes a first 1-unit sampler, an α-unit sampler, and a second 1-unit sampler connected in parallel between an output terminal of the voltage-current converter and a filtered signal output terminal, wherein each of the first 1-unit sampler, the α-unit sampler, and the second 1-unit sampler has a sampling capacitor bank for performing charge sampling. A ratio of sampling capacitances of sampling capacitor banks of the first 1-unit sampler, the α-unit sampler, and the second 1-unit sampler is 1:α:1, wherein a is adjusted to have a value between 1 and 2.

### CROSS REFERENCE TO RELATED APPLICATION

This application claims the benefit of Korean Patent Application No. 10-2012-0057414, filed on May 30, 2012, which is hereby incorporated by reference in its entirety into this application.

### BACKGROUND OF THE INVENTION

1. Technical Field

The present invention relates generally to a movement average filter based on charge sampling and a moving average filtering method using the moving average filter and, more particularly, to a movement average filter based on charge sampling and a moving average filtering method using the moving average filter, which can select the characteristics of a filter having a required form by varying the filter coefficients of the moving average filter based on charge sampling, thus efficiently eliminating interference signals such as interference waves.

2. Description of the Related Art

Discrete-time Radio Frequency (RF) technology is a field that has newly dawned in radio digital communications, and is technology for directly sampling analog RF signals transmitted over radio waves in the air and converting the analog RF signals into discrete-time sample streams that can be processed in a digital signal processing manner. In conventional radio mobile communication systems, an analog filter, a mixer, etc. have been used so as to convert analog RF signals into digital data streams enabling digital signal processing. However, it is very unrealistic to precisely control the value of an inductor reproduced by an analog filter to the value required by the frequency characteristics of the filter. In discrete-time RF technology, a direct sampling mixer and various types of Finite Impulse Response (FIR) filters, instead of an existing analog filter and mixer, are used to convert analog RF signals into the format of discrete-time sample streams. As an example of an FIR filter, a moving average filter can be contemplated. Examples of such a moving average filter include a temporal moving average filter implemented using a scheme for temporally storing charges and a spatial moving average filter implemented using a scheme for spatially storing charges.

Of these filters, a conventional spatial moving average filter implemented using a scheme for spatially storing charges has N consecutive weights of ‘1’ as filter coefficients, or has convolution weights required to obtain high-order characteristics. In relation to this, Korean Unexamined Patent Application Publication No. 2010-0001595 discloses a technology in which Finite Impulse Response (FIR) filters are connected in cascade to implement an Nth-order moving average filter. A conventional spatial moving average filter, such as that disclosed in Korean Unexamined Patent Application Publication No. 2010-0001595, is intended to obtain various filter characteristics by connecting low-order filters in several stages or by adjusting the length of a moving average so as to assign variability to the filter coefficients.

However, a conventional spatial moving average filter having N consecutive weights of a constant value is problematic in that null frequencies can be located only at frequencies (n·fₛ/D) corresponding to n times a value obtained by dividing a sampling frequency fₛ by a decimation ratio D, and in that it is difficult to eliminate some interference signals even when adjusting the length of a moving average, in order to use the null frequencies to eliminate interference signals.

### SUMMARY OF THE INVENTION

Accordingly, the present invention has been made keeping in mind the above problems occurring in the conventional moving average filter, and an object of the present invention is to provide moving average filtering technology which can vary the characteristics of a moving average filter depending on interference signals that are targeted for elimination by freely varying the filter coefficients of the moving average filter, thus improving the performance of a receiver by means of the effective elimination of interference signals while enabling the receiver to be easily designed.

Another object of the present invention is to provide moving average filtering technology in which a moving average filtering circuit is implemented using capacitors and switches, thus obtaining advantages such as the economical efficiency, portability, and low power characteristics of a digital circuit in a digital Complementary Metal Oxide Silicon (CMOS) process.

In accordance with an aspect of the present invention to accomplish the above objects, there is provided a moving average filter based on charge sampling, including a voltage-current converter for converting an input voltage signal (V_{IN}) into an input current signal (I_{RF}) and outputting the input current signal (I_{RF}); and a first sampling unit including a first 1-unit sampler, an α-unit sampler, and a second 1-unit sampler connected in parallel between an output terminal of the voltage-current converter and a filtered signal output terminal, wherein each of the first 1-unit sampler, the α-unit sampler, and the second 1-unit sampler has a sampling capacitor bank for performing charge sampling on the input current signal (I_{RF}), wherein a ratio of sampling capacitances of sampling capacitor banks of the first 1-unit sampler, the α-unit sampler, and the second 1-unit sampler is 1:α:1, wherein a is adjusted to have a value between 1 and 2.

Preferably, the first sampling unit may sequentially and repeatedly perform a first operation of the first 1-unit sampler storing an amount of charge having a 1-unit weight and performing charge sampling on the input current signal (I_{RF}) in response to a first clock pulse signal, a second operation of the α-unit sampler storing an amount of charge having an α-unit weight and performing charge sampling on the input current signal (I_{RF}) in response to a second clock pulse signal, a third operation of the second 1-unit sampler storing an amount of charge having a 1-unit weight and performing charge sampling on the input current signal (I_{RF}) in response to a third clock pulse signal, a fourth operation of outputting a moving average filtered signal (V_{OUT}), obtained by summing and averaging amounts of charge respectively stored in the first 1-unit sampler, the α-unit sampler, and the second 1-unit sampler, to the filtered signal output terminal in response to a fourth clock pulse signal, and a fifth operation of the first 1-unit sampler, the α-unit sampler, and the second 1-unit sampler individually performing a reset operation in response to a fifth clock pulse signal.

Preferably, each of the first and second 1-unit samplers may include a sampling switch unit connected at a first end to the output terminal of the voltage-current converter and connected at a second end to a first node, a read switch unit connected at a first end to the first node and connected at a second end to the filtered signal output terminal, and a 1-unit sampling capacitor bank and a reset switch unit connected in parallel between the first node and a ground.

Preferably, the α-unit sampler may include a sampling switch unit connected at a first end to the output terminal of the voltage-current converter and connected at a second end to a second node, a read switch unit connected at a first end to the second node and connected at a second end to the filtered signal output terminal, and an α-unit sampling capacitor bank and a reset switch unit connected in parallel between the second node and the ground.

Preferably, the 1-unit sampling capacitor bank may be configured such that seven capacitor-switch pairs, each having a sampling capacitor and a switch connected in series, are connected in parallel.

Preferably, the α-unit sampling capacitor bank may be configured such that a first capacitor-switch unit having seven parallel-connected capacitor-switch pairs, a second capacitor-switch unit having four parallel-connected capacitor-switch pairs, a third capacitor-switch unit having two parallel-connected capacitor-switch pairs, and a fourth capacitor-switch unit having a single capacitor-switch pair, are connected in parallel, and each of the capacitor-switch pairs is configured such that a sampling capacitor and a switch are connected in series.

Preferably, the α-unit sampler may be configured such that ON/OFF operations of switches constituting the capacitor-switch pairs are controlled by a digital control word, thus enabling sampling capacitance of the α-unit sampling capacitor bank to be adjusted.

Preferably, the first 1-unit sampler, the α-unit sampler, and the second 1-unit sampler may be configured such that ON-resistances of sampling switch units thereof are individually adjusted so that a time constant which is a product of an ON-resistance of a corresponding sampling switch unit and a capacitance of a corresponding sampling capacitor bank is identical among the first 1-unit sampler, the α-unit sampler, and the second 1-unit sampler.

Preferably, the moving average filter may further include second to fifth sampling units, each including a first 1-unit sampler, an α-unit sampler, and a second 1-unit sampler connected in parallel between the output terminal of the voltage-current converter and the filtered signal output terminal, wherein each of the first 1-unit sampler, the α-unit sampler, and the second 1-unit sampler performs charge sampling on the input current signal (I_{RF}), wherein each of the second to fifth sampling units sequentially and repeatedly performs operations corresponding to the first to fifth operations in response to consecutive clock pulse signals starting from any one of different second to fifth clock pulse signals.

In accordance with another aspect of the present invention to accomplish the above objects, there is provided a moving average filtering method based on charge sampling, including a voltage-current converter converting an input voltage signal (V_{IN}) into an input current signal (I_{RF}) and outputting the input current signal (I_{RF}); performing a first operation of a first 1-unit sampler storing an amount of charge having a 1-unit weight and performing charge sampling on the input current signal (I_{RF}) in response to a first clock pulse signal; performing a second operation of an α-unit sampler storing an amount of charge having an α-unit weight and performing charge sampling on the input current signal (I_{RF}) in response to a second clock pulse signal; performing a third operation of a second 1-unit sampler storing an amount of charge having a 1-unit weight and performing charge sampling on the input current signal (I_{RF}) in response to a third clock pulse signal; performing a fourth operation of outputting a moving average filtered signal (V_{OUT}), obtained by summing and averaging amounts of charge respectively stored in the first 1-unit sampler, the α-unit sampler, and the second 1-unit sampler, to a filtered signal output terminal in response to a fourth clock pulse signal; and performing a fifth operation of the first 1-unit sampler, the α-unit sampler, and the second 1-unit sampler individually performing a reset operation in response to a fifth clock pulse signal.

Preferably, the first to fifth operations may be sequentially and repeatedly performed.

Preferably, the first 1-unit sampler, the α-unit sampler, and the second 1-unit sampler may have a ratio of sampling capacitances of 1:α:1, wherein a is adjusted to have a value between 1 and 2.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a diagram showing the configuration of a moving average filter based on charge sampling according to the present invention;

FIG. 2 is a diagram showing in detail the configuration of a 1-unit sampler shown in FIG. 1;

FIG. 3 is a diagram showing in detail the configuration of an α-unit sampler shown in FIG. 1;

FIG. 4 is a diagram showing clock pulse signals input to each of sampling units shown in FIG. 1;

FIG. 5 is a diagram showing a state in which the transfer function of a moving average filter based on charge sampling according to the present invention is represented in a complex plane;

FIG. 6 is a diagram showing a frequency versus magnitude graph for the transfer function of the moving average filter based on charge sampling;

FIG. 7 is a diagram showing in detail the configuration of the 1-unit sampling capacitor bank of a 1-unit sampler shown in FIG. 2;

FIG. 8 is a diagram showing in detail the configuration of an α-unit sampling capacitor bank in the α-unit sampler of FIG. 3; and

FIG. 9 is a flowchart showing a moving average filtering method based on charge sampling according to the present invention.

### DESCRIPTION OF THE PREFERRED EMBODIMENTS

The present invention will be described in detail below with reference to the accompanying drawings. In the following description, redundant descriptions and detailed descriptions of known functions and elements that may unnecessarily make the gist of the present invention obscure will be omitted. Embodiments of the present invention are provided to fully describe the present invention to those having ordinary knowledge in the art to which the present invention pertains. Accordingly, in the drawings, the shapes and sizes of elements may be exaggerated for the sake of clearer description.

Hereinafter, the configuration and operation of a moving average filter based on charge sampling according to the present invention will be described with reference to the attached drawings.

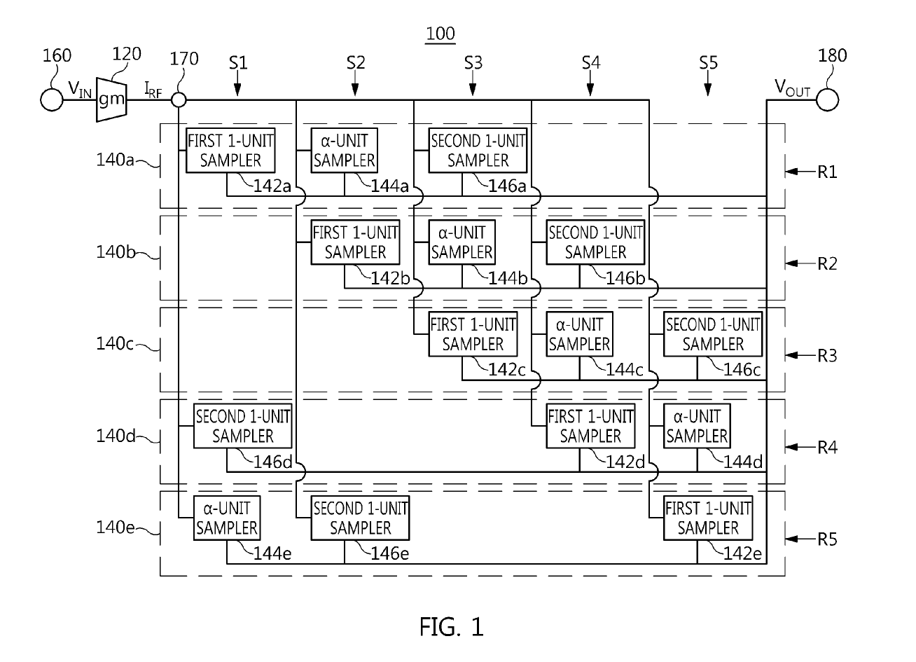

FIG. 1 is a diagram showing the configuration of a moving average filter based on charge sampling according to the present invention.

Referring to FIG. 1, a moving average filter 100 based on charge sampling according to the present invention includes a voltage-current converter 120 for converting an input voltage signal into a current signal, and first to fifth sampling units 140a to 140e for performing charge sampling on the current signal output from the voltage-current converter 120 in response to sequential clock signals, and outputting moving average-filtered signals for the current signal.

The voltage-current converter 120 converts an input voltage signal V_{IN} having a voltage form, which is input via a signal input terminal 160, into an input current signal I_{RF} having a current form, which enables charge sampling to be performed, and then outputs the input current signal I_{RF} to an output terminal 170 because the moving average filter 100 according to the present invention basically performs moving average filtering depending on a charge sampling scheme. In this case, the voltage-current converter 120 can be implemented as a transconductance amplifier and then convert the input voltage signal V_{IN} into the input current signal I_{RF}.

The first to fifth sampling units 140a to 140e individually perform charge sampling on the input current signal I_{RF}, provided by the voltage-current converter 120 and output to the output terminal 170, and output resulting moving average filtered signals to a filtered signal output terminal 180. For this, each of the first to fifth sampling units 140a to 140e includes two 1-unit samplers and one α-unit sampler which are connected in parallel between the output terminal 170 of the voltage-current converter 120 and the filtered signal output terminal 180. In greater detail, as shown in FIG. 1, the first sampling unit 140a includes a first 1-unit sampler 142a, an α-unit sampler 144a, and a second 1-unit sampler 146a which are connected in parallel between the output terminal 170 and the filtered signal output terminal 180. The second sampling unit 140b includes a first 1-unit sampler 142b, an α-unit sampler 144b, and a second 1-unit sampler 146b which are connected in parallel between the output terminal 170 and the filtered signal output terminal 180. The third sampling unit 140c includes a first 1-unit sampler 142c, an α-unit sampler 144c, and a second 1-unit sampler 146c which are connected in parallel between the output terminal 170 and the filtered signal output terminal 180. The fourth sampling unit 140d includes a first 1-unit sampler 142d, an α-unit sampler 144d, and a second 1-unit sampler 146d which are connected in parallel between the output terminal 170 and the filtered signal output terminal 180. The fifth sampling unit 140e includes a first 1-unit sampler 142e, an α-unit sampler 144e, and a second 1-unit sampler 146e which are connected in parallel between the output terminal 170 and the filtered signal output terminal 180.

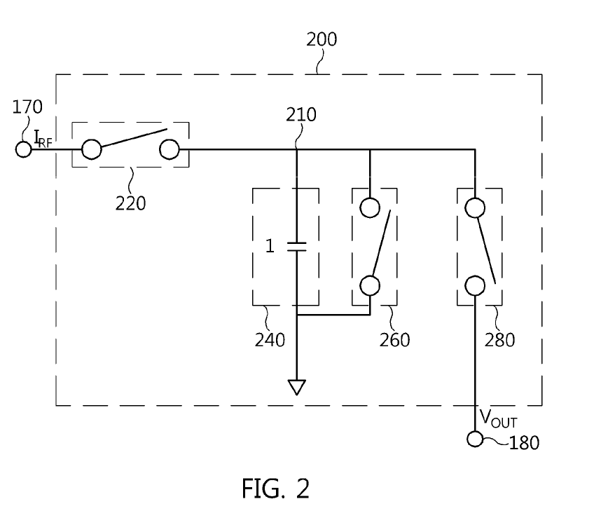

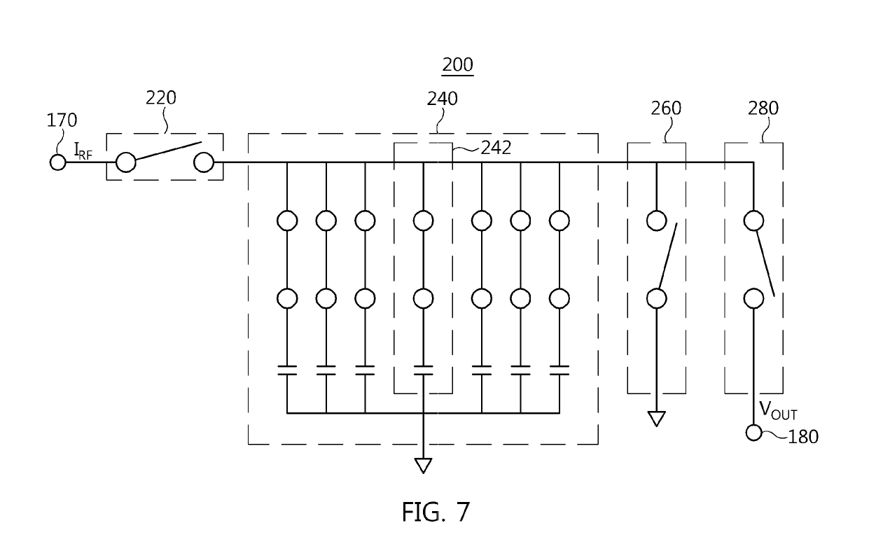

In detail, the respective 1-unit samplers 142a to 142e and 146a to 146e of the first to fifth sampling units 140a to 140e have detailed configurations identical to that of a 1-unit sampler 200 as shown in FIG. 2. Referring to FIG. 2, the 1-unit sampler 200 includes a sampling switch unit 220 connected at one end to the output terminal 170 of the voltage-current converter and connected at the other end to a first node 210, a read switch unit 280 connected at one end to the first node 210 and connected at the other end to the filtered signal output terminal 180, and a 1-unit sampling capacitor bank 240 and a reset switch unit 260 which are connected in parallel between the first node 210 and a ground. Meanwhile, although shown as a single capacitor in FIG. 2, the 1-unit sampling capacitor bank 240 may be configured in such a way that a plurality of capacitor-switch pairs, each having a switch and a capacitor connected in series, are connected in parallel, as will be described later with reference to FIG. 7. The 1-unit sampler 200 turns on the sampling switch unit 220 in response to an externally input ‘sample clock pulse signal’, and then stores an amount of charge having a 1-unit weight, which has been sampled on the input current signal I_{RF}, in the 1-unit sampling capacitor bank 240. Further, the 1-unit sampler 200 turns on the read switch unit 280 in response to an externally input ‘read clock pulse signal’, and then outputs a moving average filtered signal corresponding to the amount of sample charge stored in the 1-unit sampling capacitor bank 240 to the filtered signal output terminal 180. Furthermore, the 1-unit sampler 200 turns on the reset switch unit 260 after outputting the moving average filtered signal to the filtered signal output terminal 180, and then discharges the remaining amounts of charge stored in the 1-unit sampling capacitor bank 240 to the ground.

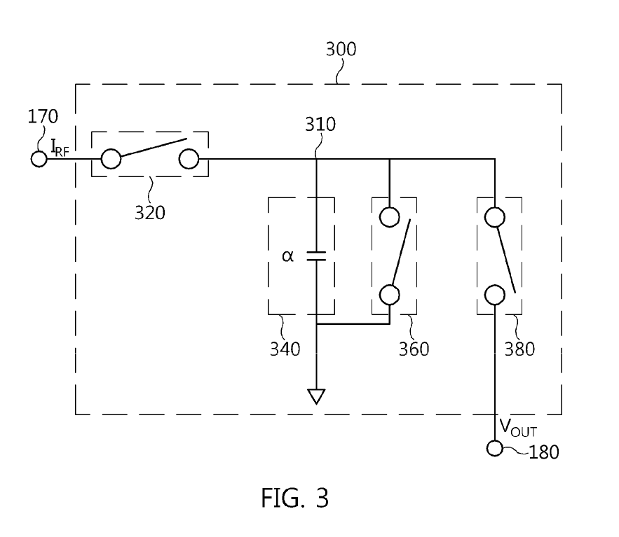

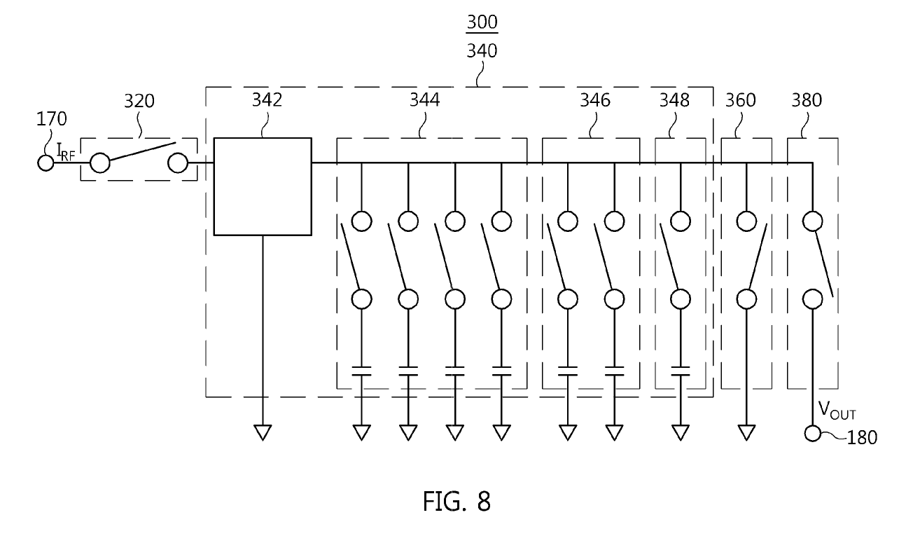

Meanwhile, the respective α-unit samplers 144a to 144e of the first to fifth sampling units 140a to 140e have detailed configurations identical to that of an α-unit sampler 300 as shown in FIG. 3. Referring to FIG. 3, the α-unit sampler 300 includes a sampling switch unit 320 connected at one end to the output terminal 170 of the voltage-current converter and connected at the other end to a second node 310, a read switch unit 380 connected at one end to the second node 310 and connected at the other end to the filtered signal output terminal 180, and an α-unit sampling capacitor bank 340 and a reset switch unit 360 which are connected in parallel between the second node 310 and the ground. Meanwhile, although shown as a single capacitor in FIG. 3, the α-unit sampling capacitor bank 340 may be configured in such a way that a plurality of capacitor-switch pairs, each having a switch and a capacitor connected in series, are connected in parallel, as will be described later with reference to FIG. 8. The α-unit sampler 300 turns on the sampling switch unit 320 in response to an externally input ‘sample clock pulse signal’, and then stores an amount of charge having an α-unit weight, which has been sampled on the input current signal I_{RF}, in the α-unit sampling capacitor bank 340. Further, the α-unit sampler 300 turns on the read switch unit 380 in response to an externally input ‘read clock pulse signal’, and then outputs a moving average filtered signal obtained by summing and averaging the amounts of sample charge stored in the α-unit sampling capacitor bank 340 to the filtered signal output terminal 180. Furthermore, the α-unit sampler 300 turns on the reset switch unit 360 in response to a subsequent clock pulse signal after outputting the moving average filtered signal to the filtered signal output terminal 180, and then discharges the remaining amount of charge stored in the α-unit sampling capacitor bank 340 to the ground.

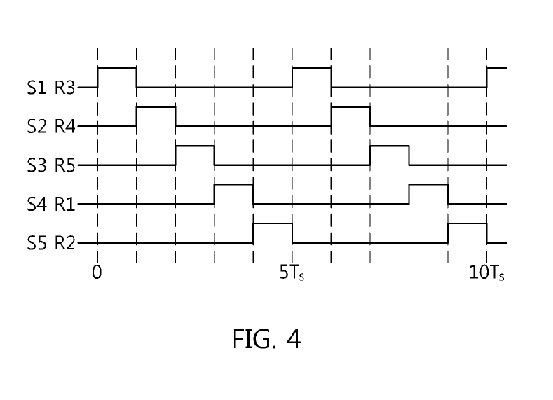

In this case, the ‘sample clock pulse signals’ that enable the first to fifth sampling units 140a to 140e of the moving average filter 100 to perform a charge sampling operation on the input current signal I_{RF} according to the present invention are denoted by S1 to S5, as shown in FIG. 4. Further, the ‘read clock pulse signals’ that enable the first to fifth sampling units 140a to 140e of the moving average filter 100 to perform the operation of outputting the moving average filtered signals, calculated by performing the charge sampling operation, to the filtered signal output terminal 180 are denoted by “R1 to R5”, as shown in FIG. 4. Further, as shown in FIG. 2, during the same time period, the clock pulse signal S1 and the clock pulse signal R3 have the same first clock pulse signal, the clock pulse signal S2 and the clock pulse signal R4 have the same second clock pulse signal, the clock pulse signal S3 and the clock pulse signal R5 have the same third clock pulse signal, the clock pulse signal S4 and the clock pulse signal R1 have the same fourth clock pulse signal, and the clock pulse signal S5 and the clock pulse signal R2 have the same fifth clock pulse signal. Meanwhile, the first to fifth clock pulse signals are sequentially input to the first to fifth sampling units 140a to 140e. After the fifth clock pulse signal has been input to the first to fifth sampling units 140a to 140e, the first to fifth clock pulse signals are repeatedly input to the first to fifth sampling units 140a to 140e.

Hereinafter, the operation of the moving average filter 100 according to the present invention will be described with reference to FIGS. 1 to 4.

First, the moving average filter 100 according to the present invention converts an input voltage signal V_{IN} into an input current signal I_{RF} using the voltage-current converter 120, and outputs the input current signal I_{RF} to the output terminal 170.

Further, the first sampling unit 140a sequentially performs a ‘sampling operation procedure’, a ‘read operation procedure’, and a ‘reset operation procedure’ in response to the clock pulse signals as shown in FIG. 4 by using the first 1-unit sampler 142a, the α-unit sampler 144a, and the second 1-unit sampler 146a. Here, the sampling operation procedure is the procedure of individually performing charge sampling on the input current signal I_{RF} output from the output terminal 170 of the voltage-current converter 120. The read operation procedure is the procedure of outputting a moving average filtered signal V_{OUT} calculated by performing charge sampling via the sampling operation procedure to the filtered signal output terminal 180. The reset operation procedure is the procedure of eliminating amounts of sample charge, remaining after the moving average filtered signal V_{OUT} calculated by performing charge sampling via the read operation procedure has been output to the filtered signal output terminal 180. Furthermore, the first sampling unit 140a repeatedly performs a single cycle in which the sampling operation procedure, the read operation procedure, and the reset operation procedure are sequentially conducted.

For this operation, at a first step, the first 1-unit sampler 142a of the first sampling unit 140a stores and samples an amount of charge X₁ having a 1-unit weight on the input current signal I_{RF} output from the output terminal 170 of the moving average filter 100 in response to the first clock pulse signal S1 or R3. Next, at a second step, the α-unit sampler 144a of the first sampling unit 140a stores and samples an amount of charge αX₂having an α-unit weight on the input current signal I_{RF} output from the output terminal 170 of the moving average filter 100 in response to the second clock pulse signal S2 or R4. Next, at a third step, the second 1-unit sampler 146a of the first sampling unit 140a stores and samples an amount of charge X₃ having a 1-unit weight on the input current signal I_{RF} output from the output terminal 170 of the moving average filter 100 in response to the third clock pulse signal S3 or R5. Further, at a fourth step, the first sampling unit 140a outputs a moving average filtered signal V_{OUT}, obtained by summing and averaging the amounts of charge X₁, αX₂, and X₃ respectively stored in the first 1-unit sampler 142a, the α-unit sampler 144a, and the second 1-unit sampler 146a, to the filtered signal output terminal 180 in response to the fourth clock pulse signal S4 or R1. Finally, at a fifth step, the first sampling unit 140a performs the reset operation of discharging the amounts of sample charge which are respectively charge-sampled and stored in the first 1-unit sampler 142a, the α-unit sampler 144a, and the second 1-unit sampler 146a at the first to third steps, to the ground in response to the fifth clock pulse signal S5 or R2 so as to perform new charge sampling on the input current signal I_{RF} output from the output terminal 170 of the moving average filter 100.

Meanwhile, as described above, the first sampling unit 140a repeatedly performs a single cycle in which the sampling operation procedure, the read operation procedure, and the reset operation procedure are sequentially conducted, in response to the clock pulse signals as shown in FIG. 4 while the second to fifth sampling units 140b to 140e also individually and repeatedly perform the above cycle. In this case, each of the second to fifth sampling units 140b to 140e performs operations corresponding to the first to fifth steps performed by the first sampling unit 140a in response to consecutive clock pulse signals starting from any one of the different clock pulse signals of the second clock pulse signal S2 or R4 to the fifth clock pulse signal S5 or R2.

In greater detail, the operation of the second sampling unit 140b will be described below. At a first step, the first 1-unit sampler 142b of the second sampling unit 140b stores and samples an amount of charge having a 1-unit weight on the input current signal I_{RF} output from the output terminal 170 of the moving average filter 100 in response to the second clock pulse signal S2 or R4. Next, at a second step, the α-unit sampler 144b of the second sampling unit 140b stores and samples an amount of charge having an α-unit weight on the input current signal I_{RF} output from the output terminal 170 of the moving average filter 100 in response to the third clock pulse signal S3 or R5. Next, at a third step, the second 1-unit sampler 146b of the second sampling unit 140b stores and samples an amount of charge having a 1-unit weight on the input current signal I_{RF} output from the output terminal 170 of the moving average filter 100 in response to the fourth clock pulse signal S4 or R1. Further, at a fourth step, the second sampling unit 140b outputs a moving average filtered signal V_{OUT}, obtained by summing and averaging the amounts of charge respectively stored in the first 1-unit sampler 142b, the α-unit sampler 144b, and the second 1-unit sampler 146b, to the filtered signal output terminal 180 in response to the fifth clock pulse signal S5 or R2. Finally, at a fifth step, the second sampling unit 140b performs the reset operation of discharging the amounts of sample charge, which are respectively charge-sampled and stored in the first 1-unit sampler 142b, the α-unit sampler 144b, and the second 1-unit sampler 146b at the first to third steps, to the ground in response to the first clock pulse signal S1 or R3 so as to perform new charge sampling on the input current signal I_{RF} output from the output terminal 170 of the moving average filter 100.

Further, the operation of the third sampling unit 140c will be described below. At a first step, the first 1-unit sampler 142c of the third sampling unit 140c stores and samples an amount of charge having a 1-unit weight on the input current signal I_{RF} output from the output terminal 170 of the moving average filter 100 in response to the third clock pulse signal S3 or R5. Next, at a second step, the α-unit sampler 144c of the third sampling unit 140c stores and samples an amount of charge having an α-unit weight on the input current signal I_{RF} output from the output terminal 170 of the moving average filter 100 in response to the fourth clock pulse signal S4 or R1. Next, at a third step, the second 1-unit sampler 146c of the third sampling unit 140c stores and samples an amount of charge having a 1-unit weight on the input current signal I_{RF} output from the output terminal 170 of the moving average filter 100 in response to the fifth clock pulse signal S5 or R2. Further, at a fourth step, the third sampling unit 140c outputs a moving average filtered signal V_{OUT}, obtained by summing and averaging the amounts of charge respectively stored in the first 1-unit sampler 142c, the α-unit sampler 144c, and the second 1-unit sampler 146c, to the filtered signal output terminal 180 in response to the first clock pulse signal S1 or R3. Finally, at a fifth step, the third sampling unit 140c performs the reset operation of discharging the amounts of sample charge, which are respectively charge-sampled and stored in the first 1-unit sampler 142c, the α-unit sampler 144c, and the second 1-unit sampler 146c at the first to third steps, to the ground in response to the second clock pulse signal S2 or R4 so as to perform new charge sampling on the input current signal I_{RF} output from the output terminal 170 of the moving average filter 100.

Further, the operation of the fourth sampling unit 140d will be described below. At a first step, the first 1-unit sampler 142d of the fourth sampling unit 140d stores and samples an amount of charge having a 1-unit weight on the input current signal I_{RF} output from the output terminal 170 of the moving average filter 100 in response to the fourth clock pulse signal S4 or R1. Next, at a second step, the α-unit sampler 144d of the fourth sampling unit 140d stores and samples an amount of charge having an α-unit weight on the input current signal I_{RF} output from the output terminal 170 of the moving average filter 100 in response to the fifth clock pulse signal S5 or R2. Next, at a third step, the second 1-unit sampler 146d of the fourth sampling unit 140d stores and samples an amount of charge having a 1-unit weight on the input current signal I_{RF} output from the output terminal 170 of the moving average filter 100 in response to the first clock pulse signal S1 or R3. Further, at a fourth step, the fourth sampling unit 140d outputs a moving average filtered signal V_{OUT}, obtained by summing and averaging the amounts of charge respectively stored in the first 1-unit sampler 142d, the α-unit sampler 144d, and the second 1-unit sampler 146d, to the filtered signal output terminal 180 in response to the second clock pulse signal S2 or R4. Finally, at a fifth step, the fourth sampling unit 140d performs the reset operation of discharging the amounts of sample charge, which are respectively charge-sampled and stored in the first 1-unit sampler 142d, the α-unit sampler 144d, and the second 1-unit sampler 146d at the first to third steps, to the ground in response to the third clock pulse signal S3 or R5 so as to perform new charge sampling on the input current signal I_{RF} output from the output terminal 170 of the moving average filter 100.

Further, the operation of the fifth sampling unit 140e will be described below. At a first step, the first 1-unit sampler 142e of the fifth sampling unit 140e stores and samples an amount of charge having a 1-unit weight on the input current signal I_{RF} output from the output terminal 170 of the moving average filter 100 in response to the fifth clock pulse signal S5 or R2. Next, at a second step, the α-unit sampler 144e of the fifth sampling unit 140e stores and samples an amount of charge having an α-unit weight on the input current signal I_{RF} output from the output terminal 170 of the moving average filter 100 in response to the first clock pulse signal S1 or R3. Next, at a third step, the second 1-unit sampler 146e of the fifth sampling unit 140e stores and samples an amount of charge having a 1-unit weight on the input current signal I_{RF} output from the output terminal 170 of the moving average filter 100 in response to the second clock pulse signal S2 or R4. Further, at a fourth step, the fifth sampling unit 140e outputs a moving average filtered signal V_{OUT}, obtained by summing and averaging the amounts of charge respectively stored in the first 1-unit sampler 142e, the α-unit sampler 144e, and the second 1-unit sampler 146e, to the filtered signal output terminal 180 in response to the third clock pulse signal S3 or R5. Finally, at a fifth step, the fifth sampling unit 140e performs the reset operation of discharging the amounts of sample charge, which are respectively charge-sampled and stored in the first 1-unit sampler 142e, the α-unit sampler 144e, and the second 1-unit sampler 146e at the first to third steps, to the ground in response to the fourth clock pulse signal S4 or R1 so as to perform new charge sampling on the input current signal I_{RF} output from the output terminal 170 of the moving average filter 100.

As described above, the moving average filter 100 of the present invention is configured such that, in accordance with the sampling, output, and reset operations performed by any one of the first to fifth sampling units 140a to 140e in response to the first to fifth clock pulse signals, the other remaining sampling units perform sampling, output and reset operations in parallel while starting from different clock pulse signals. Therefore, since the moving average filter 100 of the present invention is configured such that when any one sampling unit is incapable of performing a sampling operation on the input current signal I_{RF} while performing an output or reset operation, the sampling operation is performed on the input current signal I_{RF} by the other remaining sampling units, thus enabling continuous sampling to be performed on the input current signal I_{RF}.

Meanwhile, the ratio of the capacitances of the sampling capacitor banks of the first 1-unit sampler, the α-unit sampler, and the second 1-unit sampler, which constitute each of the first to fifth sampling units 140a to 140e of the moving average filter 100 according to the present invention, that is, ‘the capacitance of the first 1-unit sampler: the capacitance of the α-unit sampler: the capacitance of the second 1-unit sampler’ has a uniform ratio of ‘1:α:1’. Accordingly, for the input current signal I_{RF} output from the output terminal 170 of the moving average filter 100, the first 1-unit sampler can store an amount of charge X₁ having a 1-unit weight, the α-unit sampler can store an amount of charge αX₂ having an α-unit weight, and the second 1-unit sampler can store an amount of charge X₃ having a 1-unit weight. In this case, in the α-unit sampler, the value of the sampling capacitor bank thereof is adjusted by an externally input digital control word, so that the value of α can be varied to any one value ranging from 1 to 2. A procedure for controlling the α-unit sampler using a digital control word so as to vary the value of α will be described in detail later with reference to FIG. 8.

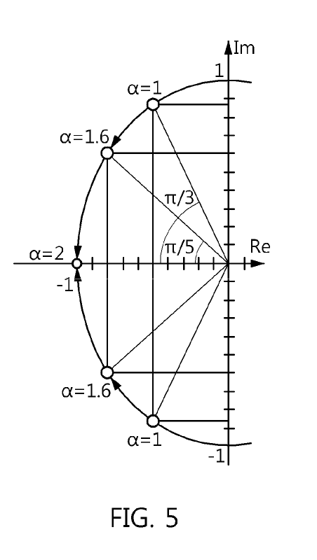

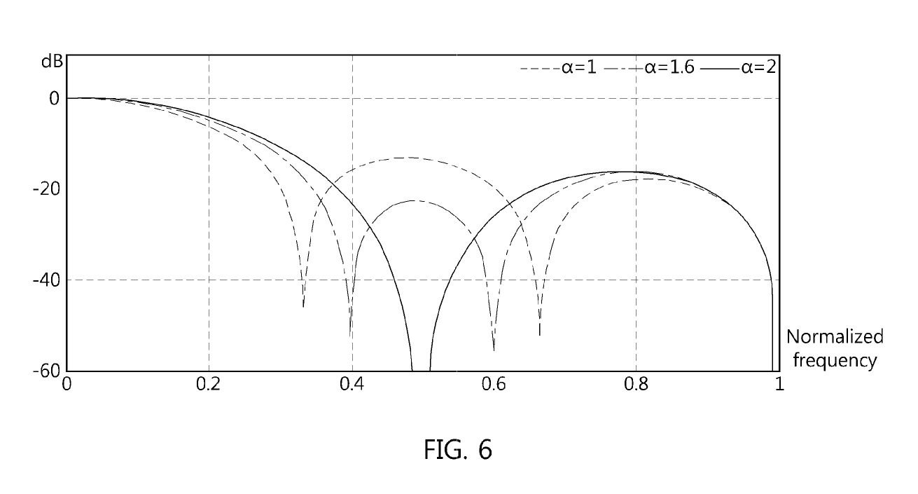

With regard to this operation, the first sampling unit 140a will be representatively described below. When the first clock pulse signal S1 or R3, the second clock pulse signal S2 or R4, and the third clock pulse signal S3 or R5 are sequentially input to the first sampling unit 140a, the first 1-unit sampler 142a of the first sampling unit 140a stores and samples an amount of charge X₁ having a 1-unit weight on the input current signal I_{RF}, the α-unit sampler 144a of the first sampling unit 140a stores and samples an amount of charge αX₂ having an α-unit weight on the input current signal I_{RF}, and the second 1-unit sampler 146a of the first sampling unit 140a stores and samples an amount of charge X₃ having a 1-unit weight on the input current signal I_{RF}. Further, the first sampling unit 140a sums the amounts of charge X₁, αX₂, and X₃ sampled by and stored in the first 1-unit sampler 142a, the α-unit sampler 144a, and the second 1-unit sampler 146a, respectively, in response to the fourth clock pulse signal S4 or R1, and stores the average amount of charge thereof In this case, the average amount of charge has a value proportional to the sum of the amounts of charge X₁, αX₂, and X₃ stored in the first 1-unit sampler 142a, the α-unit sampler 144a, and the second 1-unit sampler 146a, that is, ‘X₁+αX₂+X₃’. Accordingly, the z-domain transfer function H(z) of a moving average filtered signal V_{OUT} output to the filtered signal output terminal 180 for the input voltage signal V_{IN} becomes ‘1+αz⁻¹+z⁻² ’. In the case where the value of the filter coefficient a varies within a range from 1 to 2, when the transfer function H(z) is represented in a complex plane, it is given as shown in FIG. 5. Referring to FIG. 5, when the value of the filter coefficient a varies from 1 to 2, it can be seen that two zero points are moved towards ‘−1+j0’ on a unit circumference. That is, it can be seen that when the filter coefficient a is present between 1 and 2, a separation distance between the zero points around frequency π appears as a value between 0 and π/3. Meanwhile, as the zero points shown in FIG. 5 are moved, the form of a graph showing the frequency versus magnitude of the transfer function H(z) can be represented, as shown in FIG. 6. Referring to FIG. 6, it can be seen that the form of the graph showing the frequency versus magnitude of the transfer function H(z) is variable according to the value of α.

FIG. 7 is a diagram showing the configuration of the 1-unit sampling capacitor bank 240 of the 1-unit sampler 200 shown in FIG. 2 in detail.

Referring to FIG. 7, the 1-unit sampling capacitor bank 240 of the 1-unit sampler 200 is configured such that seven capacitor-switch pairs 242, each having a sampling capacitor and a switch connected in series, are connected in parallel. In this case, the sum of the sampling capacitances of the seven parallel-connected capacitor-switch pairs 242 is the filter coefficient of the 1-unit weight in a transfer function H(z). The capacitor-switch pairs 242 have been used to improve matching characteristics by means of linear capacitance control.

FIG. 8 is a diagram showing the configuration of the α-unit sampling capacitor bank 340 of the α-unit sampler 300 shown in FIG. 3 in detail.

Referring to FIG. 8, the α-unit sampling capacitor bank 340 of the α-unit sampler 300 is configured such that a first capacitor-switch unit 342 having seven parallel-connected capacitor-switch pairs, a second capacitor-switch unit 344 having four parallel-connected capacitor-switch pairs, a third capacitor-switch unit 346 having two parallel-connected capacitor-switch pairs, and a fourth capacitor-switch unit 348 having a single capacitor-switch pair, are connected in parallel. Although the first capacitor-switch unit 342 is not shown in detail in FIG. 8, it has the same configuration as the 1-unit sampling capacitor bank 240 shown in FIG. 7. Here, with regard to the filter coefficient of the α-unit weight in the transfer function H(z), the sampling capacitance of the first capacitor-switch unit 342 corresponds to a 1-unit weight, the sampling capacitance of the second capacitor-switch unit 344 corresponds to a 4/7-unit weight, the sampling capacitance of the third capacitor-switch unit 346 corresponds to a 2/7-unit weight, and the sampling capacitance of the fourth capacitor-switch unit 348 corresponds to a 1/7-unit weight. In this case, the second capacitor-switch unit 344, the third capacitor-switch unit 346, and the fourth capacitor-switch unit 348 are selected by a 3-bit digital control word D₂D₁D₀, and the ON/OFF operations of the switches of the capacitor-switch pairs are controlled, so that the value of the unit weight a of the α-unit sampler 300 is varied to eight different values between 1 and 2. For example, when the second capacitor-switch unit 344 and the fourth capacitor-switch unit 348 are selected by the digital control word D₂D₁D₀, the switches of the capacitor-switch pairs of the second capacitor-switch unit 344 and the fourth capacitor-switch unit 348 are turned on, and the switches of the capacitor-switch pairs of the third capacitor-switch unit 346 are turned off. Accordingly, the unit weight a of the α-unit sampler 300 has a value of ‘1+4/7+1/7=12/7’.

Meanwhile, each of the first 1-unit sampler, the α-unit sampler, and the second 1-unit sampler can store an amount of charge proportional to its own sampling capacitance for the input current signal I_{RF} only when a time constant from the output terminal 170 of the voltage-current converter 120 of FIG. 1 to a corresponding sampling capacitor bank (the product of the ON-resistance of a corresponding sampling switch unit and the sampling capacitance of the sampling capacitor bank) is identical among the first 1-unit sampler, the α-unit sampler, and the second 1-unit sampler. Therefore, in order to cause the time constants of the first 1-unit sampler, the α-unit sampler, and the second 1-unit sampler to be identical, the ON-resistances of the respective sampling switch units of the first 1-unit sampler, the α-unit sampler, and the second 1-unit sampler must be adjusted. As one exemplary scheme for this, the number of switches constituting each of the sampling switch units of the first 1-unit sampler, the α-unit sampler, and the second 1-unit sampler can be taken into consideration. In this case, for each of the first 1-unit sampler, the α-unit sampler, and the second 1-unit sampler, a sampling switch unit may be preferably implemented using a number of switches identical to the number of capacitor-switch pairs constituting a sampling capacitor bank. That is, in each of the first 1-unit sampler and the second 1-unit sampler, the sampling switch unit is preferably implemented using seven switches, whereas in the α-unit sampler, the sampling switch unit is preferably implemented using 14 switches. By the configuration of the above-described sampling switch units, the individual ON/OFF operations of switches constituting the sampling switch unit are controlled for each of the first 1-unit sampler, the α-unit sampler, and the second 1-unit sampler, and thus the product of the ON-resistance of the sampling switch unit and the sampling capacitance of the sampling capacitor bank can be adjusted so that the product is identical among the first 1-unit sampler, the α-unit sampler, and the second 1-unit sampler.

Hereinafter, a moving average filtering method based on charge sampling according to the present invention will be described. Some repeated portions identical to the operations of the moving average filter based on charge sampling according to the present invention that has been described with reference to FIGS. 1 to 8 will be omitted.

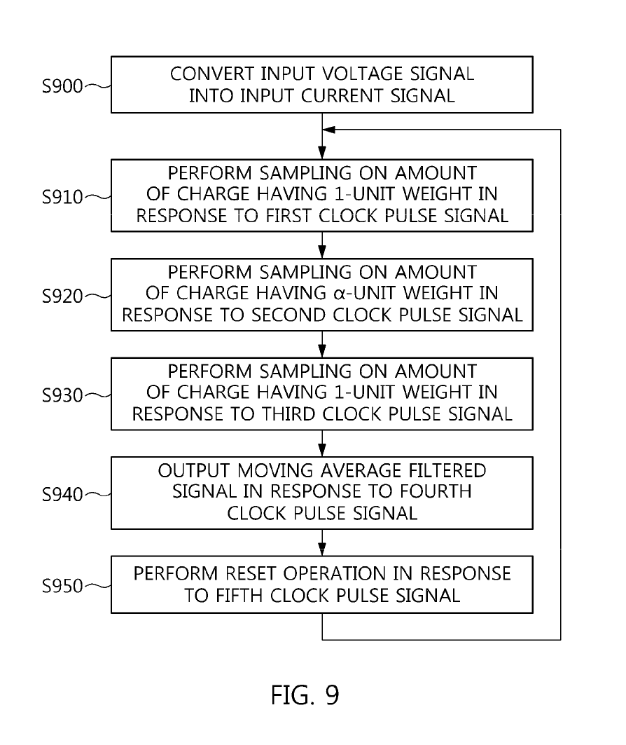

FIG. 9 is a flowchart showing a moving average filtering method based on charge sampling according to the present invention.

Referring to FIG. 9, in the moving average filtering method based on charge sampling according to the present invention, the voltage-current converter converts an input voltage signal V_{IN} into an input current signal I_{RF}, and outputs the input current signal I_{RF} at step S900.

Further, the first 1-unit sampler of the first sampling unit stores an amount of charge having a 1-unit weight and performs charge sampling on the input current signal I_{RF} output from the voltage-current converter in response to the first clock pulse signal S1 or R3 at step S910. In this case, at step S910, the second 1-unit sampler of the fourth sampling unit can store an amount of charge having a 1-unit weight and perform charge sampling on the input current signal I_{RF}, and the α-unit sampler of the fifth sampling unit can store an amount of charge having an α-unit weight and perform charge sampling on the input current signal I_{RF}. Further, at step S910, the third sampling unit can output a moving average filtered signal V_{OPT}, obtained by summing and averaging the amounts of charge respectively stored in its own samplers, that is, the first 1-unit sampler, the α-unit sampler, and the second 1-unit sampler, to the filtered signal output terminal while the second sampling unit can perform the reset operation of discharging amounts of sample charge stored in its own samplers, that is, the first 1-unit sampler, the α-unit sampler, and the second 1-unit sampler, to the ground.

Next, the α-unit sampler of the first sampling unit stores an amount of charge having an α-unit weight and performs charge sampling on the input current signal I_{RF} output from the voltage-current converter in response to the second clock pulse signal S2 or R4 at step S920. In this case, at step S920, the first 1-unit sampler of the second sampling unit stores an amount of charge having a 1-unit weight and performs charge sampling on the input current signal I_{RF}, and the second 1-unit sampler of the fifth sampling unit stores an amount of charge having a 1-unit weight and performs charge sampling on the input current signal I_{RF}. Further, at step S920, the fourth sampling unit can output a moving average filtered signal V_{OUT}, obtained by summing and averaging the amounts of charge respectively stored in its own samplers, that is, the first 1-unit sampler, the α-unit sampler, and the second 1-unit sampler, to the filtered signal output terminal while the third sampling unit can perform the reset operation of discharging amounts of sample charge stored in its own samplers, that is, the first 1-unit sampler, the α-unit sampler, and the second 1-unit sampler, to the ground.

Thereafter, the second 1-unit sampler of the first sampling unit stores an amount of charge having a 1-unit weight and performs charge sampling on the input current signal I_{RF} output from the voltage-current converter in response to the third clock pulse signal S3 or R5 at step S930. In this case, at step S930, the α-unit sampler of the second sampling unit can store an amount of charge having an α-unit weight and perform charge sampling on the input current signal I_{RF}, and the first 1-unit sampler of the third sampling unit can store an amount of charge having a 1-unit weight and perform charge sampling on the input current signal I_{RF}. Further, at step S930, the fifth sampling unit can output a moving average filtered signal V_{OUT}, obtained by summing and averaging the amounts of charge respectively stored in its own samplers, that is, the first 1-unit sampler, the α-unit sampler, and the second 1-unit sampler, to the filtered signal output terminal while the fourth sampling unit can perform the reset operation of discharging amounts of sample charge stored in its own samplers, that is, the first 1-unit sampler, the α-unit sampler, and the second 1-unit sampler, to the ground.

Next, the first sampling unit outputs a moving average filtered signal V_{OUT}, obtained by summing and averaging the amounts of charge respectively stored in its own samplers, that is, the first 1-unit sampler, the α-unit sampler, and the second 1-unit sampler, to the filtered signal output terminal at step S940. In this case, at step S940, the second 1-unit sampler of the second sampling unit can store an amount of charge having a 1-unit weight and perform charge sampling on the input current signal I_{RF}, the α-unit sampler of the third sampling unit can store an amount of charge having an α-unit weight and perform charge sampling on the input current signal I_{RF}, and the first 1-unit sampler of the fourth sampling unit can store an amount of charge having a 1-unit weight and perform charge sampling on the input current signal I_{RF}. Further, at step S940, the fifth sampling unit can perform the reset operation of discharging amounts of sample charge stored in its own samplers, that is, the first 1-unit sampler, the α-unit sampler, and the second 1-unit sampler, to the ground.

Thereafter, the first sampling unit performs the reset operation of discharging amounts of sample charge stored in its own samplers, that is, the first 1-unit sampler, the α-unit sampler, and the second 1-unit sampler, to the ground at step S950. In this case, at step S950, the second sampling unit can output a moving average filtered signal V_{OUT}, obtained by summing and averaging the amounts of charge respectively stored in its own samplers, that is, the first 1-unit sampler, the α-unit sampler, and the second 1-unit sampler, to the filtered signal output terminal. Further, at step S950, the second 1-unit sampler of the third sampling unit can store an amount of charge having a 1-unit weight and perform charge sampling on the input current signal I_{RF}, and the α-unit sampler of the fourth sampling unit can store an amount of charge having an α-unit weight and perform charge sampling on the input current signal I_{RF}, and the first 1-unit sampler of the fifth sampling unit can store an amount of charge having a 1-unit weight and perform charge sampling on the input current signal I_{RF}.

Here, steps S910 to S950 can be sequentially and repeatedly performed. Further, the first 1-unit sampler, the α-unit sampler, and the second 1-unit sampler of each of the first to fifth sampling units has a ratio of sampling capacitances of 1:α:1, wherein a can be adjusted to have a value between 1 and 2.

According to the present invention, there is an advantage in that the sampling capacitance of a moving average filter can be varied to a desired value using a digital control word, thus obtaining various filter characteristics.

Further, according to the present invention, there is an advantage in that various filter characteristics can be obtained, thus improving the degree of freedom for the design of moving average filters which are successively connected in cascade.

Furthermore, according to the present invention, there is an advantage in that the filter coefficients of a moving average filter are flexibly varied, so that interference signals such as interference waves can be efficiently eliminated, thus improving the performance of a receiver and reducing the cost of designing the receiver.

Furthermore, according to the present invention, there is an advantage in that an RF or analog region that occupies a wide area in a filtering circuit for implementing a radio communication system is replaced with a charge sampler composed of switches-capacitors suitable for a digital CMOS process, thereby reducing the overall cost required to implement the radio communication system.

As described above, optimal embodiments of the present invention have been disclosed in the drawings and the specification. Although specific terms have been used in the present specification, these are merely intended to describe the present invention and are not intended to limit the meanings thereof or the scope of the present invention described in the accompanying claims. Therefore, those skilled in the art will appreciate that various modifications and other equivalent embodiments are possible from the embodiments. Therefore, the technical scope of the present invention should be defined by the technical spirit of the claims.

What is claimed is:

1. A moving average filter based on charge sampling, comprising:
a voltage-current converter for converting an input voltage signal (V_{IN}) into an input current signal (I_{RF}) and outputting the input current signal (I_{RF}); and
a first sampling unit including a first 1-unit sampler, an α-unit sampler, and a second 1-unit sampler connected in parallel between an output terminal of the voltage-current converter and a filtered signal output terminal, wherein each of the first 1-unit sampler, the α-unit sampler, and the second 1-unit sampler has a sampling capacitor bank for performing charge sampling on the input current signal (I_{RF}),
wherein a ratio of sampling capacitances of sampling capacitor banks of the first 1-unit sampler, the α-unit sampler, and the second 1-unit sampler is 1:α:1, wherein a is adjusted to have a value between 1 and 2.

2. The moving average filter of claim 1, wherein the first sampling unit sequentially and repeatedly performs a first operation of the first 1-unit sampler storing an amount of charge having a 1-unit weight and performing charge sampling on the input current signal (I_{RF}) in response to a first clock pulse signal, a second operation of the α-unit sampler storing an amount of charge having an α-unit weight and performing charge sampling on the input current signal (I_{RF}) in response to a second clock pulse signal, a third operation of the second 1-unit sampler storing an amount of charge having a 1-unit weight and performing charge sampling on the input current signal (I_{RF}) in response to a third clock pulse signal, a fourth operation of outputting a moving average filtered signal (V_{OUT}), obtained by summing and averaging amounts of charge respectively stored in the first 1-unit sampler, the α-unit sampler, and the second 1-unit sampler, to the filtered signal output terminal in response to a fourth clock pulse signal, and a fifth operation of the first 1-unit sampler, the α-unit sampler, and the second 1-unit sampler individually performing a reset operation in response to a fifth clock pulse signal.

3. The moving average filter of claim 2, wherein each of the first and second 1-unit samplers comprises a sampling switch unit connected at a first end to the output terminal of the voltage-current converter and connected at a second end to a first node, a read switch unit connected at a first end to the first node and connected at a second end to the filtered signal output terminal, and a 1-unit sampling capacitor bank and a reset switch unit connected in parallel between the first node and a ground.

4. The moving average filter of claim 3, wherein the α-unit sampler comprises a sampling switch unit connected at a first end to the output terminal of the voltage-current converter and connected at a second end to a second node, a read switch unit connected at a first end to the second node and connected at a second end to the filtered signal output terminal, and an α-unit sampling capacitor bank and a reset switch unit connected in parallel between the second node and the ground.

5. The moving average filter of claim 4, wherein the 1-unit sampling capacitor bank is configured such that seven capacitor-switch pairs, each having a sampling capacitor and a switch connected in series, are connected in parallel.

6. The moving average filter of claim 5, wherein:
the α-unit sampling capacitor bank is configured such that a first capacitor-switch unit having seven parallel-connected capacitor-switch pairs, a second capacitor-switch unit having four parallel-connected capacitor-switch pairs, a third capacitor-switch unit having two parallel-connected capacitor-switch pairs, and a fourth capacitor-switch unit having a single capacitor-switch pair, are connected in parallel, and
each of the capacitor-switch pairs is configured such that a sampling capacitor and a switch are connected in series.

7. The moving average filter of claim 6, wherein the α-unit sampler is configured such that ON/OFF operations of switches constituting the capacitor-switch pairs are controlled by a digital control word, thus enabling sampling capacitance of the α-unit sampling capacitor bank to be adjusted.

8. The moving average filter of claim 7, wherein the first 1-unit sampler, the α-unit sampler, and the second 1-unit sampler are configured such that ON-resistances of sampling switch units thereof are individually adjusted so that a time constant which is a product of an ON-resistance of a corresponding sampling switch unit and a capacitance of a corresponding sampling capacitor bank is identical among the first 1-unit sampler, the α-unit sampler, and the second 1-unit sampler.

9. The moving average filter of claim 2, further comprising second to fifth sampling units, each including a first 1-unit sampler, an α-unit sampler, and a second 1-unit sampler connected in parallel between the output terminal of the voltage-current converter and the filtered signal output terminal, wherein each of the first 1-unit sampler, the α-unit sampler, and the second 1-unit sampler performs charge sampling on the input current signal (I_{RF}),
wherein each of the second to fifth sampling units sequentially and repeatedly performs operations corresponding to the first to fifth operations in response to consecutive clock pulse signals starting from any one of different second to fifth clock pulse signals.

10. A moving average filtering method based on charge sampling, comprising:
a voltage-current converter converting an input voltage signal (V_{IN}) into an input current signal (I_{RF}) and outputting the input current signal (I_{RF});
performing a first operation of a first 1-unit sampler storing an amount of charge having a 1-unit weight and performing charge sampling on the input current signal (I_{RF}) in response to a first clock pulse signal;
performing a second operation of an α-unit sampler storing an amount of charge having an α-unit weight and performing charge sampling on the input current signal (I_{RF}) in response to a second clock pulse signal;
performing a third operation of a second 1-unit sampler storing an amount of charge having a 1-unit weight and performing charge sampling on the input current signal (I_{RF}) in response to a third clock pulse signal;
performing a fourth operation of outputting a moving average filtered signal (V_{OUT}), obtained by summing and averaging amounts of charge respectively stored in the first 1-unit sampler, the α-unit sampler, and the second 1-unit sampler, to a filtered signal output terminal in response to a fourth clock pulse signal; and
performing a fifth operation of the first 1-unit sampler, the α-unit sampler, and the second 1-unit sampler individually performing a reset operation in response to a fifth clock pulse signal.

11. The moving average filtering method of claim 10, wherein the first to fifth operations are sequentially and repeatedly performed.

12. The moving average filtering method of claim 10, wherein the first 1-unit sampler, the α-unit sampler, and the second 1-unit sampler have a ratio of sampling capacitances of 1:α:1, wherein a is adjusted to have a value between 1 and 2.
